(19) United States
(12) Patent Application Publication
(10) Pub. No.: US 2016/0270242 A1
(43) Pub. Date: Sep. 15, 2016

(54) FLEXIBLE PRINTED CIRCUIT BOARD AND METHOD FOR MANUFACTURING SAME

(71) Applicant: AMOGREENTECH CO., LTD., Gimpo-si, Gyeonggi-do (KR)

(72) Inventors: Jong-Soo KIM, Gyeonggi-do (KR); Jeong-Sang YU, Gyeonggi-do (KR); O-Chung KWON, Chungcheongbuk-do (KR); Sung-Baek DAN, Gyeonggi-do (FR)

(21) Appl. No.: 15/036,487

(22) PCT Filed: Nov. 14, 2014
(86) PCT No.: PCT/KR2014/010947

§ 371 Date: May 13, 2016

(30) Foreign Application Priority Data
Nov. 14, 2013 (KR) 10-2013-0138595

(51) Int. Cl. H05K 3/46; H05K 1/11; H05K 3/28; H05K 1/03; H05K 3/06; H05K 1/02; H05K 1/09

(52) U.S. Cl. CPC H05K 3/467; H05K 1/028; H05K 1/0298; H05K 1/115; H05K 1/09; H05K 1/0353; H05K 3/06; H05K 3/064; H05K 3/28; H05K 2201/0145

(57) ABSTRACT

Disclosed are a flexible printed circuit board and a method of manufacturing the same, wherein a deposition seed layer is formed on a substrate, a circuit cover layer having a circuit pattern groove in the shape of a circuit pattern is formed on the deposition seed layer, the circuit pattern groove is plated with a circuit plating layer, followed by etching, thus forming a circuit pattern, thereby realizing low-resistance characteristics, reducing manufacturing costs through a simple and easy manufacturing process, and increasing productivity.

### TECHNICAL FIELD

The present invention relates to a flexible printed circuit board and a method of manufacturing the same and, more particularly, to a flexible printed circuit board and a method of manufacturing the same, wherein the flexible printed circuit board is configured such that a circuit pattern having enhanced adhesion to a substrate is formed using a deposition process, and the manufacturing cost is reduced and the manufacturing process is simplified.

This application claims the benefit of Korean Patent Application No. KR 10-2013-0138595, filed Nov. 14, 2013, which is hereby incorporated by reference in its entirety into this application.

### BACKGROUND ART

Typically, flexible printed circuit boards, which are configured such that a circuit pattern is formed on a thin insulating film, find applications in many fields including those of mobile electronic instruments, as well as automatic instruments and displays that must be flexible for their operation.

In particular, the flexible printed circuit board has been mainly employed in mobile terminals, such as smartphones, the demand for which is drastically increasing these days. For example, a flexible printed circuit board is being utilized in NFC (Near Field Communication) antennas, digitizers, etc. for mobile terminals.

Moreover, a digitizer is a device that is applied to display panels of electronic instruments including mobile phones, PDAs, laptop computers, etc. so that the coordinates of touch points are recognized and displayed, thus enabling natural writing on the display panel.

Recently, as display panels for smartphones are gradually increasing in size and tablet PCs and displays for outdoor advertisements are developed, the size of such a digitizer is increasing so as to be suitable for the size of the display panel.

Also, the digitizer is applied to an electronic blackboard in companies or educational institutions such as schools or academies because screen output is possible and writing is possible on the screen thereof, making it possible to realize smooth and accurate writing on the electronic blackboard.

The electronic blackboard is installed indoors or outdoors and is thus usable for lectures, seminars, conferences, presentations and the like, and includes a large display panel so that a large number of people can clearly see the screen.

Meanwhile, a flexible printed circuit board is formed by providing copper foil on a flexible insulating film and etching the copper foil to form a circuit pattern, or by printing a circuit pattern on a flexible insulating film using a conductive paste or conductive ink.

The flexible printed circuit board includes a terminal part for electrically connecting the circuit pattern to an additional flexible printed circuit board or a battery. The flexible printed circuit board includes two terminal parts, which are disposed adjacent to each other so as to facilitate the electrical connection. To this end, at least one of the two terminal parts is provided on the surface of the insulating film opposite the surface on which the circuit pattern is formed.

In order to connect the circuit pattern and the terminal parts, which are formed on different surfaces of the insulating film, a via hole is formed in the insulating film, and a plating layer is formed in the via hole through plating, thereby connecting the circuit pattern to the terminal parts.

The flexible printed circuit board is manufactured in a manner in which a circuit pattern is printed on the insulating film using a conductive paste and the circuit pattern is plated, or in which copper foil, laminated on the insulating film, is etched. During the use thereof, the circuit pattern may be separated from the insulating film, undesirably reducing the operational reliability of products.

In the flexible printed circuit board, the plating process for forming the via hole or the additional plating process for enhancing the rigidity of the terminal part is performed. In the plating process for forming the via hole or for enhancing the rigidity of the terminal part, the adhesion of the circuit pattern may become weak, and undesirably, the case where the circuit pattern is separated from the insulating film may occur frequently.

Also, the flexible printed circuit board is problematic because the circuit pattern is printed with a conductive paste and then plated, thus increasing the manufacturing cost and making it difficult to form the circuit pattern to a desired thickness.

Particularly in the case of a digitizer that is applied to an electronic blackboard having a large screen, the substrate has a large size so as to correspond to the large screen, undesirably causing problems in which the manufacturing cost is high during the formation of the circuit pattern, the circuit pattern is easily separated from the insulating film, and the circuit pattern is damaged and deformed due to bending and warping.

The flexible printed circuit board is manufactured so as to have a multilayer structure for effectively disposing circuits necessary for operating the device. In this case, insulating films having different circuit patterns are attached using a bonding sheet.

The flexible printed circuit board having a multilayer structure is problematic because the process for forming via holes, which electrically connects the circuit patterns of individual layers, is complicated, and the individual insulating films are integrated through the bonding process using a bonding sheet, undesirably incurring high manufacturing costs.

Furthermore, the flexible printed circuit board having a multilayer structure has difficulty in stably maintaining operational reliability upon deterioration of the adhesion of the bonding sheet, and limitations are imposed on decreasing the thickness thereof, resulting in undesirably thick products.

### DISCLOSURE

### Technical Problem

Accordingly, the present invention has been made keeping in mind the above problems encountered in the related art, and an object of the present invention is to provide a flexible printed circuit board and a method of manufacturing the same, wherein low manufacturing costs and high product reliability may be realized, and the line width and the thickness of the circuit pattern may be easily controlled.

### Technical Solution

In order to accomplish the above object, an embodiment of the present invention provides a flexible printed circuit board, comprising: a flexible substrate; and a circuit pattern provided on the substrate and formed of a conductor, wherein the circuit pattern includes a deposition seed layer formed by deposition on the substrate and a circuit plating layer formed by plating on the deposition seed layer, and the circuit plating layer is formed so as to cover only the upper surface of the deposition seed layer, other than a circumference of the deposition seed layer.

Another embodiment of the present invention provides a method of manufacturing a flexible printed circuit board, comprising: preparing a flexible substrate; forming a deposition seed layer by depositing a seed layer on the substrate; forming a circuit cover layer having a circuit pattern groove in the shape of a circuit pattern on the deposition seed layer; plating a circuit plating layer on the deposition seed layer exposed by the circuit pattern groove; and etching a portion of the deposition seed layer to form the circuit pattern.

In the present invention, the forming the deposition seed layer may be performed through vacuum deposition, and the vacuum deposition may include any one selected from among thermal evaporation, e-beam deposition, laser deposition, sputtering, and arc ion plating.

In the present invention, the vacuum deposition may be performed using, as a target material, any one selected from among copper, silver, gold, nickel, chromium, tungsten, molybdenum, and aluminum, or an alloy including at least one selected from among copper, silver, gold, nickel, chromium, tungsten, molybdenum, and aluminum.

In the present invention, the forming the circuit cover layer may include forming a photoresist layer on the deposition seed layer; and patterning a circuit pattern groove in the shape of the circuit pattern in the photoresist layer.

In the present invention, the forming the photoresist layer may be performed using any one selected from among comma roll coating, gravure coating, doctor blading, spraying, and electrospinning.

In the present invention, the preparing the substrate may include forming a via hole in the substrate, the forming the deposition seed layer may include forming a connective deposition layer that is integratedly connected to the deposition seed layer on an inner surface of the via hole while forming the deposition seed layer on the substrate, and the plating may include forming a connective plating layer on the connective deposition layer so as to be integratedly connected to the circuit plating layer while forming the circuit plating layer.

In the present invention, the preparing the substrate may include forming a primer layer on the substrate.

The method of manufacturing the flexible printed circuit board according to the present invention may further include forming a protective coating layer for covering the circuit pattern by applying a coating solution on the substrate and curing the coating solution.

In the present invention, the coating solution may contain an anti-curling agent, and the anti-curling agent may be silica.

The method of manufacturing the flexible printed circuit board according to the present invention may further include forming an additional deposition seed layer on the protective coating layer, forming an additional circuit cover layer having an additional circuit pattern groove in the shape of an additional circuit pattern on the additional deposition seed layer, plating an additional circuit plating layer on the additional deposition seed layer, exposed by the additional circuit pattern groove, and etching a portion of the additional deposition seed layer to form the additional circuit pattern.

In the present invention, the forming the protective coating layer may include applying the coating solution on an area other than a portion where the via hole is formed, when forming the protective coating layer by applying the coating solution, the forming the additional deposition seed layer may include integrally forming a connective deposition layer integratedly with the additional deposition seed layer on an inner surface of the via hole while forming the additional deposition seed layer on the protective coating layer, and the plating may include plating a connective plating layer on the connective deposition layer so as to connect the additional circuit plating layer to the circuit plating layer while forming the additional circuit plating layer.

The method of manufacturing the flexible printed circuit board according to the present invention may further include forming an additional protective coating layer for covering the additional circuit pattern by applying a coating solution on the protective coating layer and curing the coating solution.

### Advantageous Effects

According to the present invention, a circuit pattern is formed through plating on a seed layer deposited on a substrate, thus realizing low-resistance characteristics. Furthermore, it is easy to control the line width of the circuit pattern and the thickness of a circuit plating layer, thus easily designing and forming a circuit pattern having resistance characteristics desired by consumers.

According to the present invention, the manufacturing process is simple and easy, thus reducing the manufacturing cost and increasing productivity, compared to a conventional process of etching copper foil of FCCL, which is expensive.

According to the present invention, a protective layer is formed on one surface of the substrate having the circuit pattern and thus the circuit pattern is firmly maintained attached to the substrate, and damage and deformation of the circuit pattern due to repeated bending or warping of the substrate can be prevented, thus increasing operational reliability.

According to the present invention, there is no need to attach a coverlay, and the circuit pattern can be protected by the coating layer, thus increasing chemical resistance.

According to the present invention, the thickness of the flexible printed circuit board having a multilayer structure can be reduced, and thus the product using the same is made compact, and merchantability is increased.

### DESCRIPTION OF DRAWINGS

FIG. 1 is a cross-sectional view illustrating a flexible printed circuit board according to an embodiment of the present invention;

FIG. 2 is a cross-sectional view illustrating a flexible printed circuit board according to another embodiment of the present invention;

FIG. 3 is a flowchart illustrating a process of manufacturing a flexible printed circuit board according to an embodiment of the present invention;

FIG. 4 schematically illustrates the process of manufacturing the flexible printed circuit board according to the present invention of FIG. 3;

FIG. 5 is a flowchart illustrating a process of manufacturing a flexible printed circuit board according to another embodiment of the present invention;

FIGS. 6 and 7 schematically illustrate the process of manufacturing the flexible printed circuit board according to the present invention of FIG. 5; and

FIG. 8 illustrates a digitizer, which is an example of the flexible printed circuit board according to the present invention.

### DESCRIPTION OF THE REFERENCE NUMERALS IN THE DRAWINGS

1: deposition seed layer

1a: additional deposition seed layer

1b: connective deposition layer

2: circuit plating layer

2a: additional circuit plating layer

2b: connective plating layer

3: circuit cover layer

3a: circuit pattern groove

4: additional circuit cover layer

4a: additional circuit pattern groove

10: substrate

20: circuit pattern

20a: additional circuit pattern

21: circuit connector

30: protective coating layer

30a: additional protective coating layer

### BEST MODE

The present invention will be described in detail below with reference to the accompanying drawings. In the following description, redundant descriptions and detailed descriptions of known functions and elements that may unnecessarily make the gist of the present invention obscure will be omitted. Embodiments of the present invention are provided to fully describe the present invention to those having ordinary knowledge in the art to which the present invention pertains. Accordingly, in the drawings, the shapes and sizes of elements may be exaggerated for the sake of clearer description.

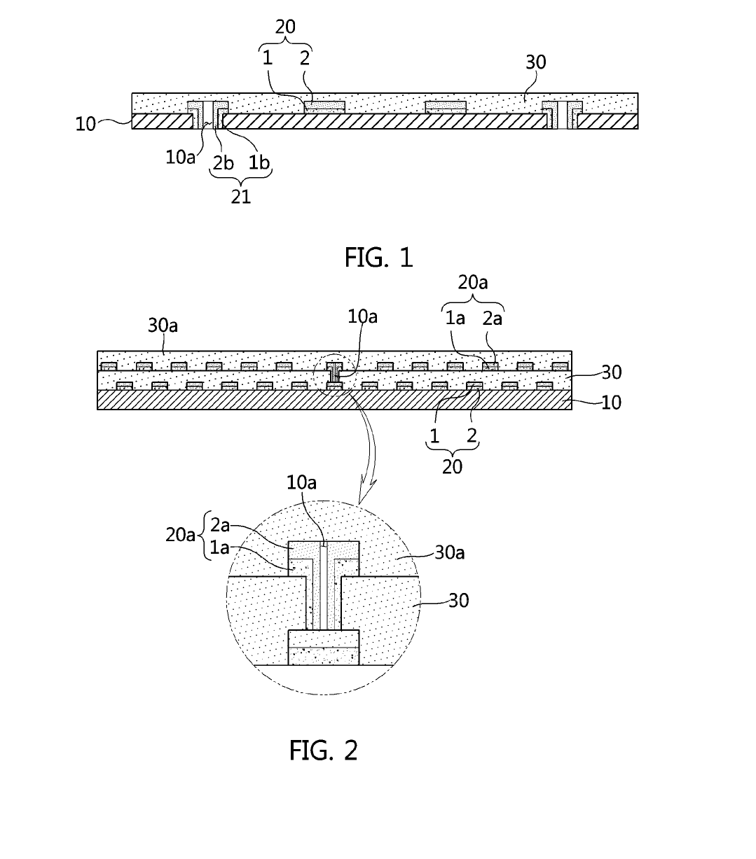

FIGS. 1 to 7 illustrate a circuit pattern 20, the line width and interval of which are exemplarily depicted to clearly explain the construction of the invention, and are different in practice. The flexible printed circuit board and the method of manufacturing the same according to the present invention may be variously modified depending on the line width and interval of the circuit pattern 20 that is actually designed.

With reference to FIG. 1, the flexible printed circuit board according to the present invention includes a substrate 10; and a circuit pattern 20, which is provided on one surface of the substrate 10 and formed of a conductor.

The circuit pattern 20 includes a deposition seed layer 1 deposited on the substrate 10; and a circuit plating layer 2 plated on the deposition seed layer 1, and the circuit plating layer 2 is formed so as to cover only the upper surface of the deposition seed layer 1, other than the circumference of the deposition seed layer 1.

Since the circuit plating layer 2 is formed so as to cover only the upper surface of the seed layer 1, other than the circumference of the seed layer 1, that is, the outer surface thereof, it does not affect the line width of the circuit pattern 20, and the line width of the circuit pattern 20 may be accurately realized in accordance with the design, whereby it is possible to adjust the resistance so as to achieve a resistance within the allowable design range.

The substrate 10 is a flexible insulating film, especially an insulating film that is very thin, flexible, and transparent or semi-transparent in order to retain the shape of the flexible printed circuit board. The insulating film may be exemplified by a PET film or a PI film. The PI film is thin and flexible, has high heat resistance and bending resistance and low dimensional variation, and is resistant to heat, and thus, is suitable for use as an insulating film when a perforated metal foil using heat is transferred. On the other hand, the PET film is relatively inexpensive compared to the PI film.

The deposition seed layer 1 is attached to the upper surface of the substrate 10 through vacuum deposition, so that adhesion to the substrate 10 is high, and it is not separated from the substrate 10 despite the warpage of the substrate 10, and the firm attachment thereof to the substrate 10 may be maintained.

The deposition seed layer 1 preferably has a thickness of 500 Å to 10,000 Å, and particularly 10 nm.

The deposition seed layer 1 is preferably composed of any one selected from among copper, silver, gold, nickel, chromium, tungsten, molybdenum, and aluminum, or an alloy including at least one selected from among copper, silver, gold, nickel, chromium, tungsten, molybdenum, and aluminum, each of which is a metal having high adhesion to the plating layer in the plating process.

The deposition seed layer 1 may be formed of copper through thermal evaporation. The base circuit layer 10 has a blackish color that eliminates light reflections, thus reducing the diffuse reflection of light, resulting in increased visibility.

The circuit plating layer 2 may be formed of any one selected from among gold (Au), silver (Ag), and copper (Cu), and may be provided on the surface of the base circuit layer 10 through electroplating.

The circuit plating layer 2 functions to lower the resistance value of the deposition seed layer 1, and may control the resistance value of the circuit pattern 20 including the deposition seed layer 1 and the circuit plating layer 2, depending on the plating thickness thereof.

The substrate 10 includes a via hole 10a that perforates the upper and lower surfaces thereof. The flexible printed circuit board according to the present invention further includes a circuit connector 21, which is formed in the via hole 10a so that the circuit pattern 20 is electrically connected to an additional circuit pattern 20a on a further surface of the substrate 10.

The circuit connector 21 includes a connective deposition layer 1b, deposited on the inner surface of the via hole 10a, and a connective plating layer 2b, stacked on the connective deposition layer 1b.

The connective deposition layer 1b is integratedly formed with the deposition seed layer 1 when the deposition seed layer 1 is formed, and the connective plating layer 2b is integratedly formed with the circuit plating layer 2 when the circuit plating layer 2 is formed.

The circuit pattern 20 preferably includes a primer layer, which is interposed between the substrate 10 and the deposition seed layer 1.

The primer layer is interposed between the substrate 10 and the deposition seed layer 1, so that the deposition seed layer 1 may be more firmly maintained in the state of being attached onto the substrate 10, rather than being directly deposited on the substrate 10.

The primer layer is disposed between the deposition seed layer 1 and the substrate 10 so that the deposition seed layer 1 may be maintained in a state of being firmly attached onto the substrate 10, and may be formed of acryl polyurethane.

The primer resin may be a heat-resistant liquid resin, and any resin may be used so long as it enhances the adhesion of the deposition seed layer 1 on the substrate 10.

Also, the flexible printed circuit board according to the present invention preferably further includes a protective coating layer 30 for covering the circuit pattern 20.

The protective coating layer 30 is formed so as to cover and protect the circuit pattern 20 by applying a liquid coating solution on the substrate 10 and curing it.

The protective coating layer 30 is formed as a synthetic resin coating layer using the same type of coating solution as in the substrate 10, and thus may be more efficiently attached to the substrate 10 and may be more firmly integrated with the substrate 10. The substrate 10 is a PI film, and the protective coating layer 30 may be a PI coating layer or a PAI coating layer.

The protective coating layer 30 is preferably formed of a coating solution containing an anti-curling agent, and the anti-curling agent may be silica.

In the case where the protective coating layer 30 is formed on only one surface of the substrate 10, curling may occur from the ends of the substrate 10 due to shrinkage of the protective coating layer 30 upon curing the applied coating solution.

The anti-curling agent functions to prevent curling of the ends of the substrate 10 due to shrinkage of the protective coating layer 30 so that the substrate 10 having the protective coating layer 30 becomes maximally flat.

The protective coating layer 30 is preferably formed to a thickness of at least 9 μm, and more preferably 10 μm or more, on the circuit pattern 20. This is the minimum thickness necessary for the function of the insulating layer for insulating the circuit pattern 20. For example, when the thickness of the circuit pattern 20 is 10 μm, the protective coating layer 30 is formed to a thickness of 19 μm or more on the substrate 10. When the thickness of the circuit pattern 20 is 15 μm, the protective coating layer 30 may be formed to a thickness of 24 μm or more.

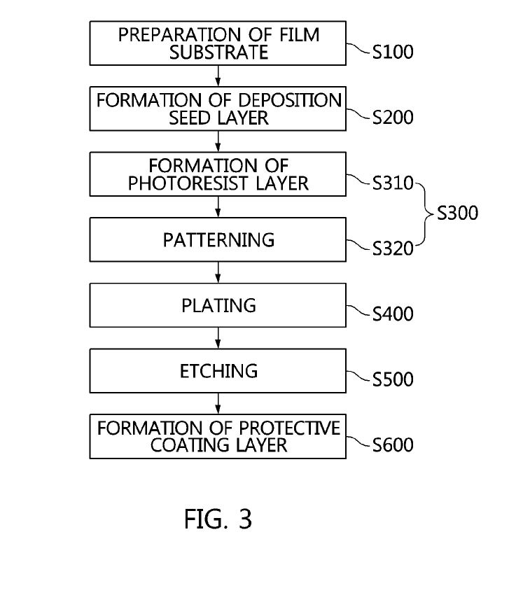

With reference to FIG. 2, the flexible printed circuit board according to an embodiment of the present invention may further include an additional circuit pattern 20a that is formed on the protective coating layer 30.

The additional circuit pattern 20a includes an additional deposition seed layer 1a deposited on the protective coating layer 30, and an additional circuit plating layer 2a plated on the additional deposition seed layer 1a.

The additional deposition seed layer 1a is the same as the deposition seed layer 1, and the additional circuit plating layer 2a is the same as the circuit plating layer, and a redundant description thereof is thus omitted.

The additional circuit pattern 20a preferably further includes a primer layer that is interposed between the protective coating layer 30 and the additional deposition seed layer 1a.

The primer layer functions to fixedly attach the additional deposition seed layer 1a onto the protective coating layer 30.

The primer layer is the same as described above, and a redundant description thereof is thus omitted.

The protective coating layer 30 includes therein a via hole 10a. According to an embodiment of the present invention, the flexible printed circuit board further includes a circuit connector 21 that is formed in the via hole 10a so as to connect the additional circuit pattern 20a on the protective coating layer 30 to the circuit pattern 20 on the substrate 10.

The circuit connector 21 includes a connective deposition layer 1b, deposited on the inner surface of the via hole 10a, and a connective plating layer 2b, formed on the connective deposition layer 1b.

The connective deposition layer 1b is formed together with the formation of the additional deposition seed layer 1a, and is thus integratedly formed with the additional deposition seed layer 1a, and the connective plating layer 2b is plated on the connective deposition layer 1b together with the plating of the additional circuit plating layer 2 of the additional circuit pattern 20a and is thus integratedly formed with the additional circuit plating layer 2a to thereby integratedly connect it to the circuit plating layer 2.

The connective deposition layer 1b is the same as the deposition seed layer, and the connective plating layer 2b is the same as the circuit plating layer 2, and a redundant description thereof is thus omitted.

Of an X-axis coordinate recognition pattern part including a plurality of X-axis electrodes spaced apart from each other in a transverse direction and a Y-axis coordinate recognition pattern part including a plurality of Y-axis electrodes spaced apart from each other in a longitudinal direction, any one may be the circuit pattern 20 formed on the substrate 10 and the other may be the additional circuit pattern 20a formed on the protective coating layer 30.

The flexible printed circuit board according to an embodiment of the present invention is exemplified by a digitizer configured such that, of the X-axis coordinate recognition pattern part and the Y-axis coordinate recognition pattern part, any one is formed on the substrate 10 and the other is formed on the surface of the protective coating layer 30 to determine the coordinates of touch points. The X-axis coordinate recognition pattern part and the Y-axis coordinate recognition pattern part are electrically conducted to each other through the circuit connector 21, which is provided in the via hole 10a formed in the protective coating layer 30.

The circuit pattern 20 may be provided in a grid form, composed of a plurality of sets of X-Y coordinates on the surface of the substrate 10 and the surface of the protective coating layer 30.

An additional protective coating layer 30a is formed on the protective coating layer 30 so as to cover and protect the additional circuit pattern 20a, and an additional circuit pattern 20a may be formed on the additional protective coating layer 30a.

The additional protective coating layer 30a is the same as the protective coating layer 30, and a redundant description thereof is omitted.

According to an embodiment of the present invention, the flexible printed circuit board may be provided in the form of a multilayer structure in which a plurality of protective coating layers is formed and a plurality of circuit pattern layers are formed on the respective protective coating layers.

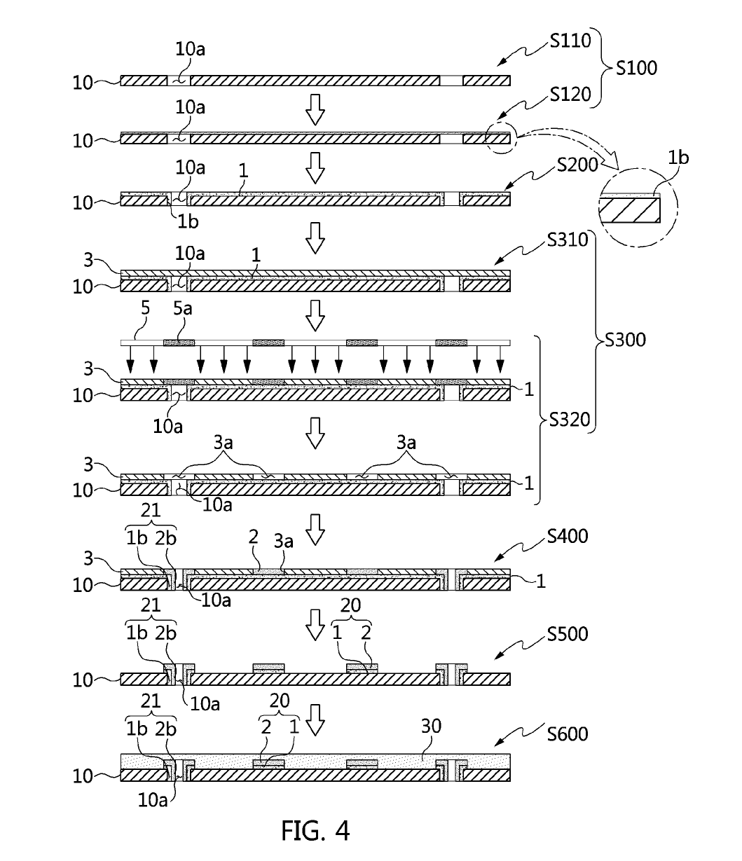

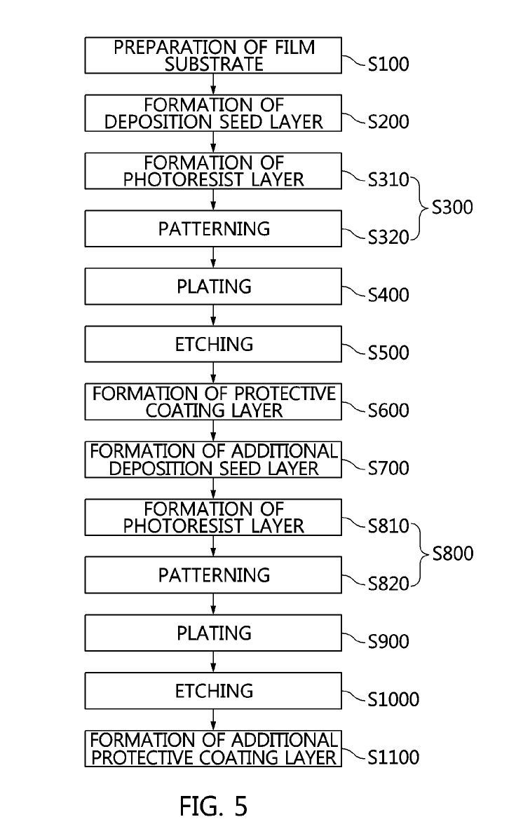

FIG. 3 is a flowchart illustrating the process of manufacturing the flexible printed circuit board according to an embodiment of the present invention, and FIG. 4 schematically illustrates the process of manufacturing the flexible printed circuit board of FIG. 3. With reference to FIGS. 3 and 4, the method of manufacturing the flexible printed circuit board according to the present invention includes the steps of preparing a flexible substrate 10 (S100), forming a deposition seed layer 1 by depositing a seed layer on the substrate 10 (S200), forming a circuit cover layer 3 having a circuit pattern groove 3a in the shape of the circuit pattern 20 on the deposition seed layer 1 (S300), plating a circuit plating layer 2 on the deposition seed layer 1 exposed by the circuit pattern groove 3a (S400), and performing etching to form the circuit pattern 20 (S500). Removing the circuit cover layer 3 (not shown) is performed between the plating step (S400) and the etching step (S500), so that the circuit plating layer 2 is used as a barrier in the etching step (500) and thus a portion of the deposition seed layer 1 is etched.

In the step of forming the deposition seed layer 1 (S200), the deposition seed layer 1 is formed through vacuum deposition, and the vacuum deposition may include any one selected from among thermal evaporation, e-beam deposition, laser deposition, sputtering, and arc ion plating.

The vacuum deposition is carried out using, as a target material, any one selected from among copper, silver, gold, nickel, chromium, tungsten, molybdenum, and aluminum, or an alloy including at least one selected from among copper, silver, gold, nickel, chromium, tungsten, molybdenum, and aluminum, whereby the deposition seed layer 1 is preferably formed on the substrate 10.

The step of forming the circuit cover layer 3 (S300) includes forming a photoresist layer on the deposition seed layer 1 (S310) and patterning the circuit pattern groove 3a in the shape of the circuit pattern 20 in the photoresist layer (S320).

The circuit pattern groove 3a is provided in the form of being vertically perforated to thus expose the deposition seed layer 1.

The circuit cover layer 3 may be formed of a photoresist layer.

The photoresist layer may be a dry film, or may be formed by applying a photoresist solution.

Compared to the photoresist layer formed by applying the photoresist solution, the dry film has a uniform thickness, obviates the need for a drying process to thus simplify the manufacturing process, enables the circuit pattern 20 to be uniformly formed at a regular thickness, and is favorable in terms of fining the line width of the circuit electrode. Hence, the circuit pattern groove 3a having a negative pattern with a line width of 15 μm or less may be more easily formed.

The forming of the photoresist layer (S210) may be performed using any one selected from among comma roll coating, gravure coating, doctor blading, spraying, and electrospinning.

The electrospinning process enables the electrospun photoresist layer to be formed to a thickness of 1 to 10 μm. The electrospinning process is performed in a manner in which electric power is applied to the deposition seed layer 1 and a photosensitive polymer solution is sprayed together with compressed air using an electrospinning nozzle, and thus the electrospun photoresist layer is formed on the deposition seed layer 1.

The photosensitive polymer, which is sprayed in the electrospinning process, contains electric charges, whereby the photosensitive polymer solution does not agglomerate while being sprayed, and is efficiently sprayed, yielding an electrospun photoresist layer in the form of a thin film having a thickness of 5 μm or less.

In the electrospinning process, the electrospun photoresist layer is formed on the deposition seed layer 1 under the condition that electric power is applied to the deposition seed layer 1. The photosensitive fibers produced while the photosensitive polymer solution is sprayed are uniformly applied on and strongly attached to the deposition thin film layer 1 due to the potential difference therebetween.

In the case where the photoresist layer is formed using the electrospinning process, the photoresist layer applied through electrospinning has to be cured, and the photoresist layer is cured using UV curing, laser curing, or e-beam curing.

The patterning (S220) is performed in a manner in which only the portion where the circuit pattern groove 3a is formed is covered with a mask 5, the photoresist layer is exposed and developed using a developing solution, whereby the portion that is not cured upon exposure, that is, the portion covered with the mask 5, is dissolved in the developing solution, thus forming the circuit pattern groove 3a in the photoresist layer.

The portion of the photoresist layer that is exposed to light is insoluble, and does not dissolve in the developing solution.

The exposure process is carried out such that only the portion of the photoresist layer, which is not covered with the mask 5 and is thus irradiated with light, is not dissolved by the developing solution, and the portion of the photoresist layer that is not irradiated with light is dissolved in the developing solution.

In the development process using the developing solution, the portion of the photoresist layer that is soluble in the developing solution, that is, only the portion of the photoresist layer corresponding to the circuit pattern groove 3a, is removed, thus forming the circuit pattern groove 3a.

In the plating step (S400), gold (Au), silver (Ag) or copper (Cu) is subjected to electroplating or electroless plating, thereby forming the plating layer 2 in the circuit pattern groove 3a. In the plating step (S400), the circuit plating layer 2 is formed using the photoresist layer as a barrier in the circuit pattern groove 3a, whereby the circuit plating layer 2 is stacked only on the deposition seed layer 1, and the circuit plating layer 2 is not formed on the circumference corresponding to the outer surface of the deposition seed layer 1, thus forming a circuit plating layer 2 having a fine line width that accurately matches the line width of the circuit pattern groove 3a.

In the etching step (S500), the photoresist layer is removed, and a portion of the deposition seed layer 1 is etched using the plating layer 2 as a barrier so that the deposition seed layer 1 has a line width corresponding to the plating layer 2.

Thus, a circuit pattern 20 having a line width that accurately matches the line width of the circuit pattern groove 3a may be formed.

The step of preparing the substrate 10 (S100) includes forming a via hole 10a in the substrate 10 (S110), and the step of forming the deposition seed layer 1 (S200) includes forming the connective deposition layer 1b that is integratedly connected to the deposition seed layer 1 on the inner surface of the via hole 10a while forming the deposition seed layer 1 on the substrate 10. The plating step (S400) includes forming the connective plating layer 2b that is stacked on the connective deposition layer 1b and is integratedly connected to the circuit plating layer 2 while forming the circuit plating layer 2.

Any circuit pattern groove 3a resulting from the patterning process (S320) may be formed to open the via hole 10a, and the connective plating layer 2b may be formed in the via hole 10a through the circuit pattern groove 3a, which opens the via hole 10a.

The step of preparing the substrate 10 (S100) may include forming a primer layer 1b on the substrate 10 (S120). The forming of the primer layer 1b is preferably carried out after the forming of the via hole 10a (S110), whereby the primer layer 1b may be applied on the inner surface of the via hole 10a.

The forming of the primer layer 1b (S120) may be performed in a manner in which the primer layer 1b for enhancing adhesion between the substrate 10 and the deposition layer upon vacuum deposition is applied on one surface of the substrate 10. The primer layer 1b is formed of acryl polyurethane.

The forming of the primer layer 1b (S120) may be performed in a manner in which a liquid primer agent is applied, dried, or thermally treated, thus curing the primer agent.

The primer resin may be exemplified by a heat-resistant liquid resin, and any resin may be used so long as it enhances the adhesion of the deposition seed layer 1 on the substrate 10.

The method of manufacturing the flexible printed circuit board according to the present invention preferably further includes forming a protective coating layer on the substrate 10 so as to cover and protect the circuit pattern 20 (S600).

The step of forming the protective coating layer 30 (S600) is performed in a manner in which a coating solution is applied on the substrate 10, dried and cured, thus forming a protective coating layer 30 that covers and protects the circuit pattern 20 on the substrate 10.

The step of forming the protective coating layer 30 (S600) includes curing the applied coating solution by heating it at 200 to 450° C. for 20 to 50 min.

The coating solution is composed of a PI (polyimide) solution, achieved by dissolving 15 to 35 wt % of PI in a solvent. The solvent may be diluted NMP.

The coating solution may be a PAI solution, and the protective coating layer 30 may be formed by applying the PAI solution. The PAI solution is formed by dissolving 15 to 35 wt % of PAI in a solvent. The solvent may be diluted NMP.

The coating solution preferably further includes an anti-curling agent, and the anti-curling agent may be silica. The coating solution is preferably a PI solution including 2 to 5 wt % of silica or a PAI solution including 2 to 5 wt % of silica, and more preferably a PI solution or a PAI solution including 2.5 wt % of silica.

Specifically, the PI solution may be composed of 15 to 35 wt % of PI, 2 to 5 wt % of silica, and the remainder of the solvent, and the PAI solution may be composed of 15 to 35 wt % of PAI, 2 to 5 wt % of silica, and the remainder of the solvent.

The anti-curling agent is used to prevent the curling of ends of the substrate 10 after the protective coating layer 30 is cured.

The protective coating layer 30 formed by applying the coating solution on the substrate 10 is dried and cured. In this case, while the protective coating layer 30 shrinks, the ends of the substrate 10 may curl. The anti-curling agent is contained in the coating solution in order to prevent the curling of the ends of the substrate 10 due to the shrinkage of the protective coating layer 30 when the protective coating layer 30 is cured.

When silica is contained in an amount of 2 to 5 wt % in the PI or PAI solution, the curling may be minimized, as has been experimentally proven.

In the step of forming the protective coating layer 30 (S600), the coating solution, applied on one surface of the substrate 10, is dried by heating it at 90 to 150° C. for 5 to 25 min.

In the step of forming the protective coating layer 30 (S600), the protective coating layer 30 is preferably formed to a thickness of at least 9 μm, and more preferably 10 μm or more, on the circuit pattern 20. This is the minimum thickness necessary for the function of the insulating layer for insulating the circuit pattern 20.

In the step of forming the protective coating layer 30 (S600), the coating solution may be applied through screen printing on one surface of the substrate 10, and the thickness of the coating solution that is applied may be adjusted by varying the mesh size of the screen in the screen printing process.

The protective coating layer 30 is preferably formed through a single screen-printing process to simplify the manufacturing process and reduce manufacturing costs. Screen printing is preferably conducted using a mesh screen having a mesh size of 40 to 100 mesh per square inch, which means that the number of openings per square inch is 40 to 100. When the PI solution or PAI solution is applied on the substrate 10 using a mesh screen having a mesh size of 40 to 100 mesh per square inch, the protective coating layer 30 may be formed to a thickness of at least 9 μm on the circuit pattern 20.

The step of forming the protective coating layer 30 (S600) preferably includes applying the coating solution on the substrate 10 through screen printing using a waterproof mesh screen.

The waterproof mesh screen readily passes the coating solution therethrough and thus enables a coating solution having high viscosity, namely the PI solution or the PAI solution, to be applied on the substrate 10, whereby the protective coating layer 30 may be formed to be thicker through a single coating process. It is easy to form a protective coating layer 30 having a thickness of at least 9 μm on the circuit pattern 20 through a single coating process.

The protective coating layer 30 functions to protect the circuit pattern 20 formed on one surface of the substrate 10 and to more firmly attach the circuit pattern 20 to the substrate 10, and is responsible for preventing the circuit pattern 20 from being separated from the substrate 10 even upon warping of the substrate 10.

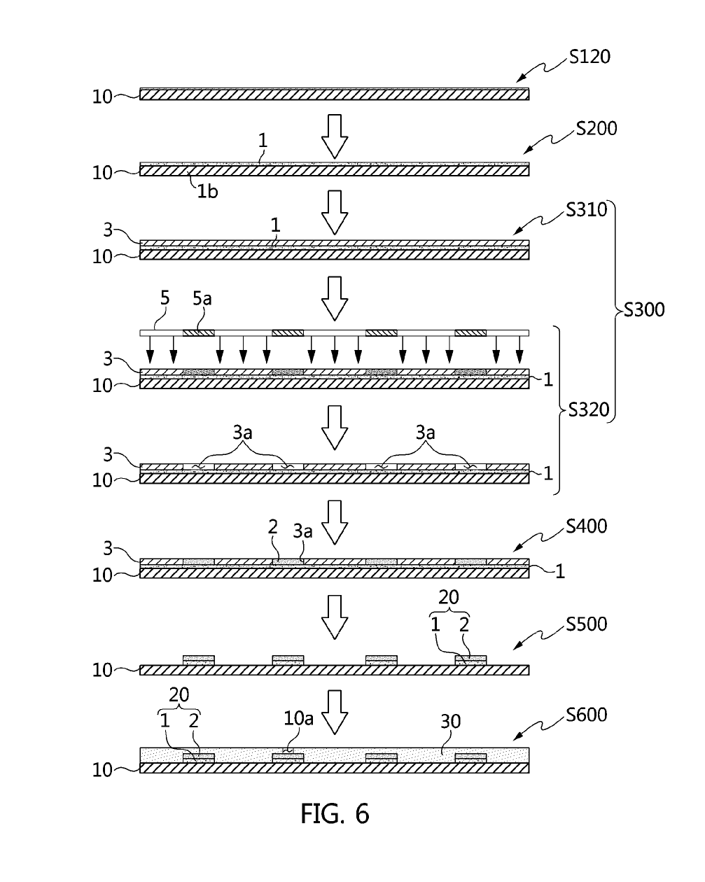

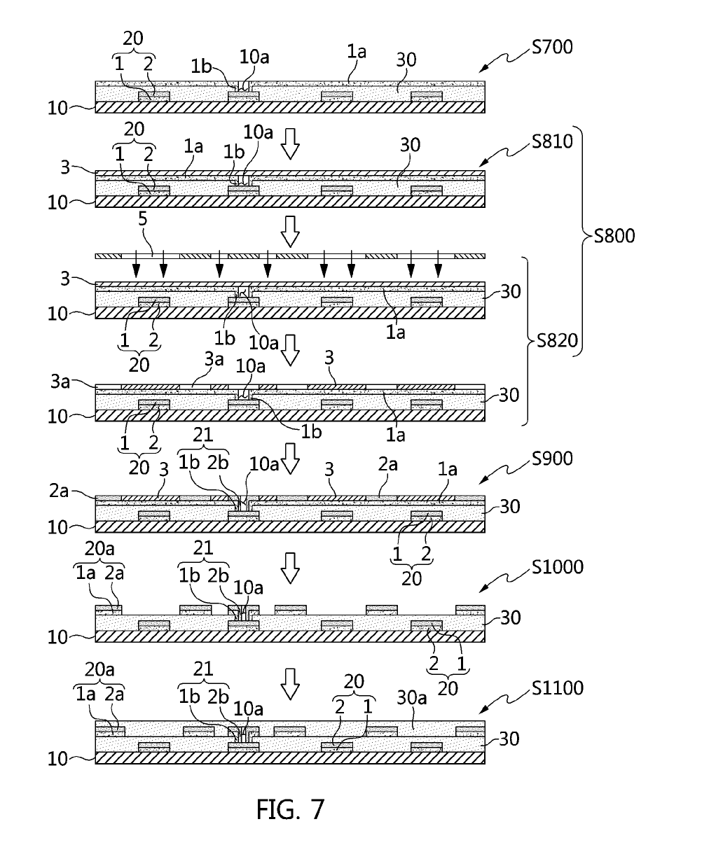

FIG. 5 is a flowchart illustrating the process of manufacturing a flexible printed circuit board according to another embodiment of the present invention, and FIGS. 6 and 7 schematically illustrate the process of manufacturing the flexible printed circuit board according to the present invention. FIG. 6 schematically illustrates the step of preparing a substrate (S100) to the step of forming a protective coating layer (S600), and FIG. 7 schematically illustrates the step of forming an additional deposition seed layer 1a (S700) to the step of forming an additional protective coating layer 30a (S1100).

With reference to FIGS. 5 to 7, the method of manufacturing a flexible printed circuit board according to another embodiment of the present invention is described below, and the step of preparing the film (S100) includes forming a primer layer 1b on the substrate 10 (S110).

The step of forming the protective coating layer (S600) preferably includes applying the coating solution on an area other than a portion where the via hole 10a is formed, yielding the protective coating layer 30. Thereby, the via hole 10a may be formed in the protective coating layer 30, without the further need to form the via hole 10a after the formation of the protective coating layer 30, so that the circuit pattern 20 may be electrically connected to an additional circuit pattern 20a formed on the protective coating layer 30.

Also, the method of manufacturing a flexible printed circuit board according to the present invention further includes the steps of forming an additional deposition seed layer 1a on the protective coating layer 30 (S700), forming an additional circuit cover layer 4 having an additional circuit pattern groove 4a in the shape of an additional circuit pattern 20a on the additional deposition seed layer 1a (S800), plating an additional circuit plating layer 2a on the additional deposition seed layer 1a, exposed by the additional circuit pattern groove 4a (S900), and etching a portion of the additional deposition seed layer 1a so as to form an additional circuit pattern (S1000).

The additional circuit pattern groove 4a is provided in the form of being vertically perforated to thus expose the additional deposition seed layer 1a.

Removing the additional circuit cover layer 4 (not shown) is performed between the step of plating the additional circuit plating layer 2a (S900) and the step of etching the portion of the additional deposition seed layer 1a (S1000), so that the portion of the additional deposition seed layer 1a is etched using the additional circuit plating layer 2a as a barrier in the step of etching the portion of the additional deposition seed layer 1a (S1000).

In the step of forming the additional deposition seed layer 1a (S700), the connective deposition layer 1b is integratedly formed with the additional deposition seed layer 1a on the inner surface of the via hole 10a while forming the additional deposition seed layer 1a on the protective coating layer 30. In the plating step, the connective plating layer 2b is plated on the connective deposition layer 1b while forming the additional circuit plating layer 2a, whereby the additional circuit plating layer 2a is connected to the circuit plating layer 2.

The connective plating layer 2b is integratedly formed with the additional circuit plating layer 2a and the circuit plating layer 2, thereby electrically connecting the additional circuit plating layer 2a and the circuit plating layer 2 to each other.

The step of forming the additional circuit cover layer 4 (S800) includes forming a photoresist layer on the additional deposition seed layer 1a (S810) and patterning the additional circuit pattern groove 4a in the shape of the additional circuit pattern 20a in the photoresist layer (S220).

The additional circuit cover layer 4 is formed of a photoresist layer.

Any additional circuit pattern groove 4a resulting from the step of forming the additional circuit cover layer 4 may be formed to open the via hole 10a, whereby the connective plating layer 2b may be formed in the via hole 10a through the additional circuit pattern groove 4a, which opens the via hole 10a.

The step of forming the additional deposition seed layer 1a on the protective coating layer 30 is the same as the step of forming the deposition seed layer (S200), with the exception that the deposition seed layer is formed not on the substrate 10 but on the protective coating layer 30, and a redundant description thereof is thus omitted.

The forming of the photoresist layer and the patterning of the additional circuit pattern groove 4a (S220) are the same as in the step of forming the circuit cover layer, and a redundant description thereof is thus omitted.

Also, the method of manufacturing the flexible printed circuit board according to the present invention may further include forming a primer layer (not shown) between the step of forming the protective coating layer 30 (S600) and the step of forming the additional deposition seed layer 1a on the protective coating layer 30 (S700).

The forming of the primer layer on the protective coating layer 30 is the same as the forming of the primer layer 1b on the substrate 10, and therefore a redundant description thereof is omitted.

In the step of plating the additional circuit plating layer 2a (S900), gold (Au), silver (Ag) or copper (Cu) is subjected to electroplating or electroless plating, thereby forming the plating layer 2 in the additional circuit pattern groove 4a. In the step of plating the additional circuit plating layer 2a (S900), the additional circuit plating layer 2a is formed using the photoresist layer as a barrier in the additional circuit pattern groove 4a, whereby the additional circuit plating layer 2a is stacked only on the additional deposition seed layer 1a, and the additional circuit plating layer 2a is not formed on the circumference, which is the outer surface of the deposition seed layer 1, thus forming an additional circuit plating layer 2a having a fine line width that accurately matches the line width of the additional circuit pattern groove 4a.

In the step of etching the portion of the additional deposition seed layer 1a (S1000), the photoresist layer 3 is removed, and the portion of the additional deposition seed layer 1a is etched using the additional circuit plating layer 2a as a barrier, whereby the additional deposition seed layer 1a has a line width corresponding to that of the additional circuit plating layer 2a.

Therefore, an additional circuit pattern 20a having a line width that accurately matches the additional circuit pattern groove 4a may be formed.

Also, the method of manufacturing the flexible printed circuit board according to the present invention may further include forming an additional protective coating layer 30a on the protective coating layer 30 so as to cover the additional circuit pattern 20a.

The step of forming the additional protective coating layer 30a may be the same as the step of forming the protective coating layer, and thus a redundant description thereof is omitted.

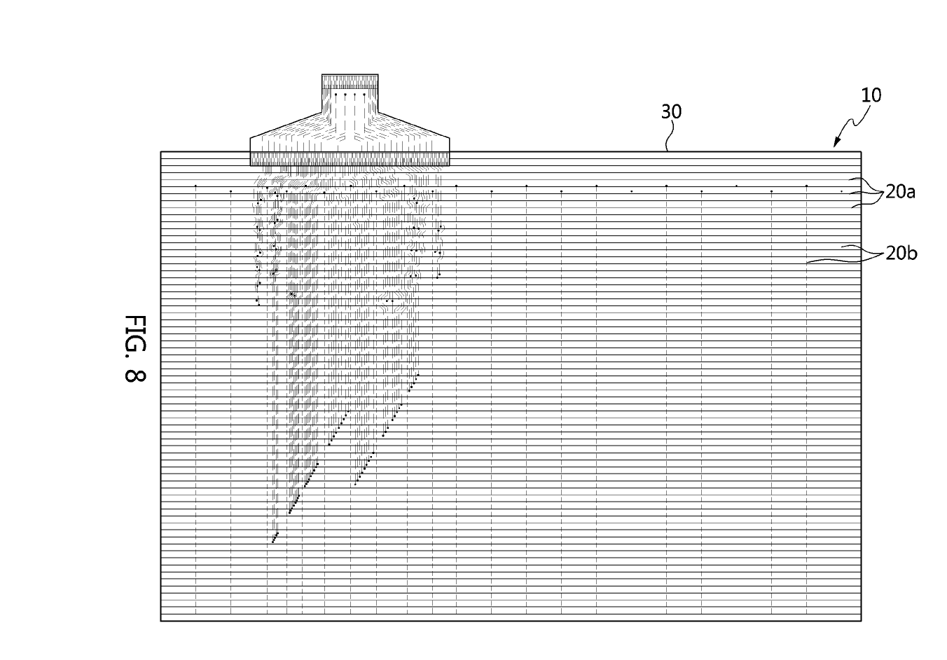

FIG. 8 illustrates a digitizer according to an embodiment of the present invention, in which the circuit pattern 20 is an X-axis coordinate recognition pattern part including a plurality of X-axis electrodes spaced apart from each other in a transverse direction and the additional circuit pattern 20a is a Y-axis coordinate recognition pattern part including a plurality of Y-axis electrodes spaced apart from each other in a longitudinal direction.

According to the present invention, in the fabrication of the digitizer illustrated in FIG. 8, the manufacturing process is simplified and the manufacturing costs are considerably reduced. As the size of the digitizer is increased, the effect thereof is enhanced, and thus the present invention is suitable for fabricating a digitizer that is applied to an electronic blackboard having a large screen.

According to the present invention, the circuit pattern is plated on the seed layer deposited on the substrate, thus realizing low-resistance characteristics. Furthermore, it is easy to control the line width of the circuit pattern and the thickness of the circuit plating layer, thus easily designing and forming a circuit pattern having resistance characteristics desired by consumers.

According to the present invention, the manufacturing process is simple and easy, thus reducing manufacturing costs and increasing productivity compared to a conventional process of etching copper foil of FCCL, which is expensive.

According to the present invention, a protective layer is applied on one surface of the substrate having the circuit pattern, and thus the circuit pattern is maintained firmly attached to the substrate, and damage and deformation of the circuit pattern due to repeated bending or warping of the substrate can be prevented, thus increasing operational reliability.

According to the present invention, there is no need to attach a coverlay, and the circuit pattern is protected by the coating layer, thus increasing chemical resistance.

According to the present invention, the thickness of the flexible printed circuit board having a multilayer structure can be reduced, and thus the product using the same is made compact, and merchantability is increased.

Although the preferred embodiments of the present invention have been disclosed for illustrative purposes, those skilled in the art will appreciate that various modifications are possible, without departing from the scope and spirit of the invention as disclosed in the accompanying claims.

1. A flexible printed circuit board, comprising:
a flexible substrate; and
a circuit pattern provided on the substrate and formed of a conductor,
wherein the circuit pattern comprises a deposition seed layer formed by deposition on the substrate and a circuit plating layer formed by plating on the deposition seed layer, and
the circuit plating layer is formed so as to cover an upper surface of the deposition seed layer, other than a circumference of the deposition seed layer.

2. The flexible printed circuit board of claim 1, wherein the deposition seed layer comprises any one selected from among copper, silver, gold, nickel, chromium, tungsten, molybdenum, and aluminum, or an alloy including at least one selected from among copper, silver, gold, nickel, chromium, tungsten, molybdenum, and aluminum.

3. The flexible printed circuit board of claim 1, wherein a via hole is formed in the substrate, and the flexible printed circuit board further comprises a circuit connector that is formed in the via hole so as to electrically connect the circuit pattern to an additional circuit pattern on a further surface of the substrate, and
the circuit connector comprises a connective deposition layer deposited on an inner surface of the via hole, and a connective plating layer formed on the connective deposition layer.

4. The flexible printed circuit board of claim 1, wherein the circuit pattern further comprises a primer layer interposed between the substrate and the deposition seed layer.

5. The flexible printed circuit board of claim 1, further comprising a protective coating layer formed so as to cover the circuit pattern by applying a coating solution on one surface of the substrate and curing the coating solution.

6. The flexible printed circuit board of claim 5, further comprising an additional circuit pattern formed on the protective coating layer,
wherein a via hole is formed in the protective coating layer,
the additional circuit pattern comprises an additional deposition seed layer, deposited on the protective coating layer, and an additional circuit plating layer, formed on the additional deposition seed layer, and
a circuit connector is provided in the via hole so as to connect the additional circuit pattern to the circuit pattern, and comprises a connective deposition layer, deposited on an inner surface of the via hole, and a connective plating layer, formed on the connective deposition layer so as to connect the circuit plating layer to the additional circuit plating layer.

7. The flexible printed circuit board of claim 6, wherein an additional protective coating layer is formed on the protective coating layer so as to cover the additional circuit pattern by applying a coating solution on the protective coating layer and curing the coating solution.

8. The flexible printed circuit board of claim 5, wherein the substrate is a PET film or a PI film, and
the protective coating layer is a PI or PAI coating layer.

9. A method of manufacturing a flexible printed circuit board, comprising:
preparing a flexible substrate;
forming a deposition seed layer by depositing a seed layer on the substrate;
forming a circuit cover layer having a circuit pattern groove in a shape of a circuit pattern on the deposition seed layer;
plating a circuit plating layer on the deposition seed layer exposed by the circuit pattern groove; and
etching a portion of the deposition seed layer to form the circuit pattern.

10. The method of claim 9, wherein the forming the deposition seed layer is performed through vacuum deposition, and
the vacuum deposition includes any one selected from among thermal evaporation, e-beam deposition, laser deposition, sputtering, and arc ion plating.

11. The method of claim 10, wherein the vacuum deposition is performed using, as a target material, any one selected from among copper, silver, gold, nickel, chromium, tungsten, molybdenum, and aluminum, or an alloy including at least one selected from among copper, silver, gold, nickel, chromium, tungsten, molybdenum, and aluminum.

12. The method of claim 9, wherein the forming the circuit cover layer comprises:
forming a photoresist layer on the deposition seed layer; and
patterning a circuit pattern groove in a shape of the circuit pattern in the photoresist layer.

13. The method of claim 12, wherein the forming the photoresist layer is performed using any one selected from among comma roll coating, gravure coating, doctor blading, spraying, and electrospinning.

14. The method of claim 9, wherein the preparing the substrate comprises forming a via hole in the substrate,
the forming the deposition seed layer comprises forming a connective deposition layer that is integratedly connected to the deposition seed layer on an inner surface of the via hole while forming the deposition seed layer on the substrate, and
the plating the circuit plating layer comprises forming a connective plating layer on the connective deposition layer so as to be integratedly connected to the circuit plating layer while forming the circuit plating layer.

15. The method of claim 9, wherein the preparing the substrate comprises forming a primer layer on the substrate.

16. The method of claim 9, further comprising forming a protective coating layer for covering the circuit pattern by applying a coating solution on the substrate and curing the coating solution.

17. The method of claim 16, wherein the coating solution contains an anti-curling agent, and the anti-curling agent is silica.

18. The method of claim 16, further comprising:
forming an additional deposition seed layer by depositing a seed layer on the protective coating layer;
forming an additional circuit cover layer having an additional circuit pattern groove in a shape of an additional circuit pattern on the additional deposition seed layer;
plating an additional circuit plating layer on the additional deposition seed layer, exposed by the additional circuit pattern groove; and
etching a portion of the additional deposition seed layer to form the additional circuit pattern.

19. The method of claim 18, wherein the forming the protective coating layer comprises applying the coating solution on an area other than a portion where the via hole is formed when forming the protective coating layer by applying the coating solution,
the forming the additional deposition seed layer comprises integratedly forming a connective deposition layer integratedly with the additional deposition seed layer on an inner surface of the via hole while forming the additional deposition seed layer on the protective coating layer, and
the plating the additional circuit plating layer comprises plating a connective plating layer on the connective deposition layer so as to connect the additional circuit plating layer to the circuit plating layer while forming the additional circuit plating layer.

20. The method of claim 18, further comprising forming an additional protective coating layer for covering the additional circuit pattern by applying a coating solution on the protective coating layer and curing the coating solution.
